(19) United States
(12) Patent Application Publication
(10) Pub. No.: US 2026/0072072 A1
(43) Pub. Date: Mar. 12, 2026

(54) Aliasing-Based Broadband Noise Power Estimation for Arc-Fault Detection

(71) Applicant: ABB Schweiz AG, Baden (CH)

(72) Inventors: David Salido Monzú, Zürich (CH); Edgar Albert Engel, Nussbaumen (CH); Christoph Winkelmann, Bern (CH); Cecil Rivers, West Hartford, CT (US); Shannon Woolfolk, Gainesville, VA (US); Craig Benson, Herndon, VA (US)

(73) Assignee: ABB Schweiz AG, Baden (CH)

(21) Appl. No.: 18/829,431

(22) Filed: Sep. 10, 2024

(51) Int. Cl. G01R 31/14; H02H 3/16

(52) U.S. Cl. CPC G01R 31/14; H02H 3/16

(57) ABSTRACT

A current signal from a current sensor of an electrical network is obtained. The current signal is transformed to a voltage signal. A certain range of frequencies of the voltage signal are selected using a filter. The certain range of frequencies of the voltage signal are amplified. The amplified certain range of frequencies of the voltage signal are converted from analog to an aliased digitized signal using an undersampling scheme. A power of the aliased digitized signal is computed.

### FIELD

The present disclosure relates to a method and system for estimating noise power on electrical signals using an undersampling scheme for improving arc-fault detection performance.

### BACKGROUND

Arc-fault detection devices protect electrical installations from producing fire hazards induced by electrical arcs on damaged cables and connectors. These devices are typically composed of an arc-fault detection stage monitoring the currents on the electrical network, and a switch interrupting said currents when arc-fault events are detected. Arc-fault detection generally relies on a combination of low-frequency waveform characteristics and distinctive broadband noise-like signals induced by arcing phenomena on the load currents.

For the latter, the relatively large bandwidth and frequencies where relevant information is contained enforces strong trade-offs on the acquisition performance so that cost and space constraints of arc-detection products are met. Consequently, only partial and inaccurate information from relevant spectral bands and time windows is typically acquired and used for arc-fault detection.

### SUMMARY

An embodiment of the present disclosure provides a computer-implemented method for computing a parameter associated with an arc-fault by analyzing a current signal including obtaining the current signal from a current sensor of an electrical network, transforming the current signal to a voltage signal, selecting a certain range of frequencies of the voltage signal using a filter, amplifying the certain range of frequencies of the voltage signal, converting the amplified certain range of frequencies of the voltage signal from analog to an aliased digitized signal using an undersampling scheme, and computing a power of the aliased digitized signal.

In an embodiment, the computer-implemented method further includes providing the computed power to an external component of the electrical network.

In an embodiment, the external component is configured to detect an arc-fault in the electrical network by comparing the computed power to a threshold.

In an embodiment, the external component is configured to trip a circuit breaker of the electrical network based on detecting the arc-fault.

In an embodiment, the undersampling scheme uses a sampling rate that is less than a minimum sampling rate defined by a Nyquist-Shannon sampling theorem for the selected certain range of frequencies of the voltage signal.

In an embodiment, computing the power includes squaring and time averaging the aliased digitized signal.

In an embodiment, the time averaging is performed in millisecond time scales.

In an embodiment, the undersampling scheme uses an undersampling rate of at least 64 kilosamples per second and the certain range of frequencies is from 1 megahertz (MHz) to 3 MHz.

In an embodiment, the filter is implemented by a band pass filter that includes a certain number of capacitors and a certain number of resistors arranged between a current-voltage component, an operational amplifier, and an analog-to-digital conversion component.

In an embodiment, the current signal is transformed to the voltage signal via the current-voltage component, the certain range of frequencies of the voltage signal are amplified via the amplifier, and the amplified certain range of frequencies of the voltage signal are converted from analog to the aliased digitized signal by the analog-to-digital conversion component, the analog-to-digital conversion component using a certain undersampling rate of the undersampling scheme, the power computed by a feature computation component.

In an embodiment, the certain range of frequencies is based on reference data associated with arc-faults detected in a controlled environment.

Another embodiment of the present disclosure provides a computer system for computing a parameter associated with an arc-fault in an electrical network by analyzing a current signal, the computer system including one or more hardware processors which, alone or in combination, are configured to provide for execution of the following steps: obtaining the current signal from a current sensor of the electrical network, transforming the current signal to a voltage signal, selecting a certain range of frequencies of the voltage signal using a filter, amplifying the certain range of frequencies of the voltage signal, converting the amplified certain range of frequencies of the voltage signal from analog to an aliased digitized signal using an undersampling scheme, and computing a power of the aliased digitized signal.

In an embodiment of the computer system, the steps further include providing the computed power to an external component of the electrical network.

In an embodiment of the computer system, the external component is configured to detect the arc-fault in the electrical network by comparing the computed power to a threshold.

In an embodiment of the computer system, the external component is configured to trip a circuit breaker of the electrical network based on detecting the arc-fault.

In an embodiment of the computer system, the undersampling scheme uses a sampling rate that is less than a minimum sampling rate defined by a Nyquist-Shannon sampling theorem for the selected certain range of frequencies of the voltage signal.

In an embodiment of the computer system, computing the power includes squaring and time averaging the aliased digitized signal.

Another embodiment of the present disclosure provides a tangible, non-transitory computer-readable medium having instructions thereon which, upon being executed by one or more processors, provide for computing a parameter associated with an arc-fault in an electrical network by analyzing a current signal by execution of the following steps: obtaining the current signal from a current sensor of the electrical network, transforming the current signal to a voltage signal, selecting a certain range of frequencies of the voltage signal using a filter, amplifying the certain range of frequencies of the voltage signal, converting the amplified certain range of frequencies of the voltage signal from analog to an aliased digitized signal using an undersampling scheme, and computing a power of the aliased digitized signal.

In an embodiment of the tangible, non-transitory computer-readable medium, the steps further include providing the computed power to an external component of the electrical network.

In an embodiment of the tangible, non-transitory computer-readable medium, the external component is configured to detect the arc-fault in the electrical network by comparing the computed power to a threshold, and wherein the external component is further configured to trip a circuit breaker of the electrical network based on detecting the arc-fault.

### BRIEF DESCRIPTION OF THE DRAWINGS

The present disclosure will be described in even greater detail below based on the exemplary figures. The disclosure is not limited to the exemplary embodiments. All features described and/or illustrated herein can be used alone or combined in different combinations in embodiments of the disclosure. The features and advantages of various embodiments of the present disclosure will become apparent by reading the following detailed description with reference to the attached drawings which illustrate the following:

FIG. 1 illustrates an example schematic architecture for arc-fault detection including low and high-frequency acquisition channels, according to embodiments of the present disclosure;

FIG. 2 illustrates an example undersampling process that depicts spectral overlapping induced by undersampling assuming a flat bandpass noise figure, according to embodiments of the present disclosure;

FIG. 3 illustrates an example architecture for acquiring bandpass noise in an undersampling scheme, according to embodiments of the present disclosure;

FIG. 4 illustrates an example implementation architecture for acquiring bandpass noise in an undersampling scheme, according to embodiments of the present disclosure;

FIG. 5 illustrates an example flow chart for computing a parameter associated with an arc-fault by analyzing a current signal, according to embodiments of the present disclosure; and

FIG. 6 illustrates a simplified block diagram of one or more devices or systems for computing a parameter associated with an arc-fault by analyzing a current signal according to embodiments of the present disclosure.

### DETAILED DESCRIPTION

Embodiments of the present disclosure provide a method and system for computing a parameter associated with an arc-fault by analyzing a current signal. While the present disclosure is described primarily in connection with machines, systems, or components operated in a residential or industrial setting or environment, such as machines or systems associated with breaker boxes, electrical protection systems, switchgears, and circuit breakers, as would be recognized by a person of ordinary skill in the art, the disclosure is not so limited and inventive features apply to other components or systems of electrical networks.

According to aspects of the present disclosure, a novel undersampling scheme system is described which provides solutions to problems associated with conventional arc-fault detection. For example, the undersampling scheme features described herein leverage information from current signals in a high frequency domain or regime that purposely use an undersampling rate that enables an accurate estimation of how much power exists in a current signal within a certain frequency band. The undersampling rate implemented by the systems described herein subvert the Nyquist-Shannon Sampling theorem such that the signal is distorted such that the reconstruction of the original signal is not possible. Put another way, the systems of the present disclosure utilize an undersampling rate that observes the signal at a lower rate than should be necessary for reconstructing it properly. However, the information that is obtained using the undersampling process can still be used to make an accurate estimation of the total power of the original signal within frequency bands which are most important for arc-fault detection. Conventional methods instead utilize information from both the low frequency and high frequency regimes as well as sampling rates which are in accordance with the Nyquist-Shannon Sampling theorem to determine whether an arc-fault is present in an electrical network. Such conventional systems that utilize such methods typically require larger and more expensive components to properly capture signals at a faster rate than the current signal, or only acquire lower frequency bands with less informative arc-fault related information, thus degrading the detection performance of such conventional systems.

In an exemplary embodiment, systems and methods implementing the undersampling scheme features described herein utilize a signal acquisition scheme (undersampling scheme) based on undersampling a bandpass region whose bandwidth is significantly larger than a sampling rate of a digitizing system. The noise figure within this region is heavily aliased in the process resulting in severe distortion and power overlapping within the Nyquist band. However, the integrated noise within this region provides a close estimation of the noise power of the original band. Exploiting this feature provides access to continuous broadband noise power estimation using minimal conditioning electronics and low-speed digitization. This type of system significantly impacts the detection performance of practical implementations by enhancing the most informative arc-induced observable (i.e. the power of the current signal).

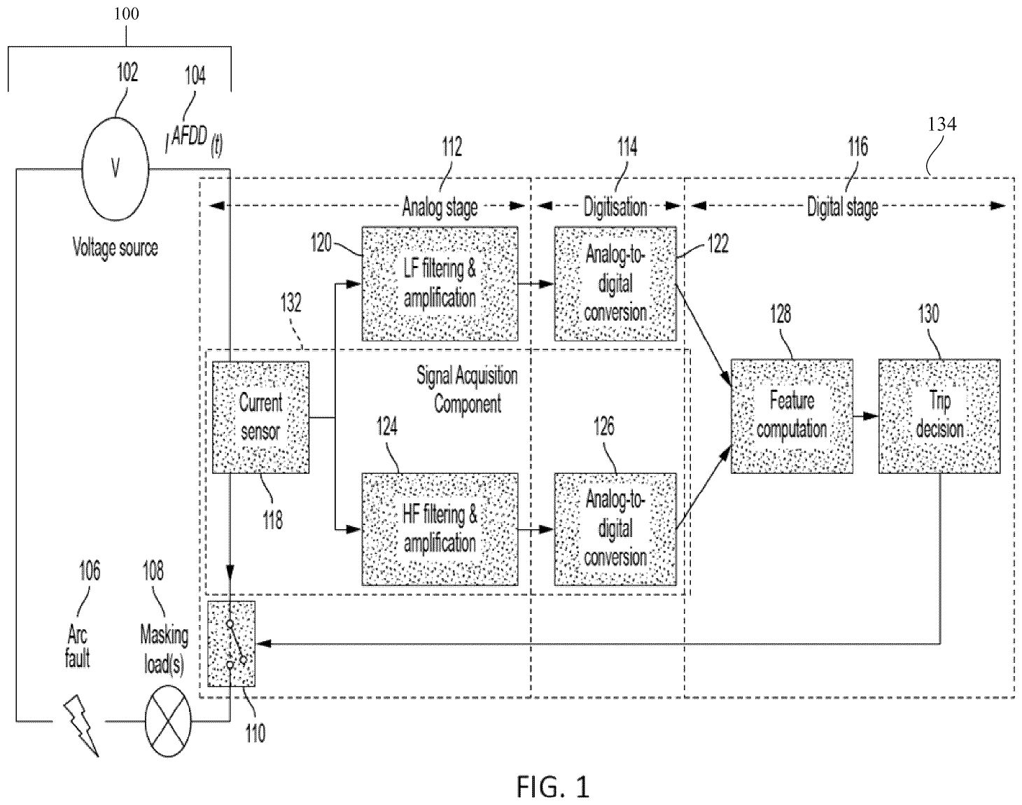

FIG. 1 illustrates an example schematic architecture for arc-fault detection including low and high-frequency acquisition channels, according to embodiments of the present disclosure. FIG. 1 depicts an electrical network 100 that includes voltage source 102 representing the line voltage, current 104 flowing through the electrical network 100, a represented arc-fault 106, and masking loads 108. An arc fault detection device 134, composed of a circuit breaker (110) and an electronic arc-fault detection system (112, 114, 116) is connected to the electrical network 100. FIG. 1 also depicts the stages of such an arc-fault detection system including an analog stage 112, digitization 114, and a digital stage 116. The arc-fault detection system of FIG. 1 includes a current sensor 118 for obtaining a current signal of the electrical network 100. In embodiments, the current sensor 118 may be configured to convert the current signal to a voltage signal. Typical arc-fault detection systems use information from both low-frequency and high-frequency regimes acquired via, for example, a low-frequency filtering and amplification component 120 and analog-to-digital conversion component 122. Although embodiments described herein describe determining whether an arc-fault exists or is present in an electrical network using the computed power from the high-frequency regime of the current flowing through the electrical network, the embodiments disclosed herein are not so limited. For example, information, metrics, or parameters derived from the current signal, and in particular data from the low-frequency regime or other parameters from the high-frequency regime may be combined with the computed power to determine the presence of an arc-fault in the electrical network 100. The combined parameters or metrics may be compared to a single or multidimensional threshold derived from reference data to determine the presence of an arc-fault in the electrical network 100.

The arc-fault detection device 134 of FIG. 1 includes a high-frequency filtering and amplification component (high-frequency filterer and high-frequency amplifier) 124 as well as analog-to-digital conversion component (analog-to-digital converter) 126. The digital stage 116 includes a feature computation component (feature computation) 128 as well as trip decision component (trip decider) 130. The high-frequency filterer and high-frequency amplifier 124 may be configured to filter certain range of frequencies of the voltage signal as well as amplify the certain range of frequencies of the voltage signal. In embodiments, the analog-to-digital converter 126 may be configured to convert the amplified certain range of frequencies of the voltage signal from analog to an aliased digitized signal using an undersampling scheme as described herein. The feature computation 128 may be configured to compute the power of the aliased digitized signal as well as obtain or determine other parameters used for arc-fault detection such as features from the low-frequency regime of the current flowing through the electrical network. The trip decider 130 may be configured to compare certain parameters, such as the computed power from the feature computation 128, to one or more thresholds and determine if an arc-fault is present in the electrical network 100. The certain parameters or other information analyzed by the trip decider 130 may include information related to the waveform of the low-frequency signal or the stability of the signal from cycle to cycle. In scenarios where the trip decider 130 determines that an arc-fault is present in the electrical network 100, the trip decider 130 may generate and transmit instructions for tripping the breaker as depicted at 110 of FIG. 1. FIG. 1 also depicts signal acquisition component 132 for obtaining high-frequency information of the analog input, such as current 104, and providing a digitized format of the input after conversion, selection, amplification, etc., to a digital component such as feature computation 128.

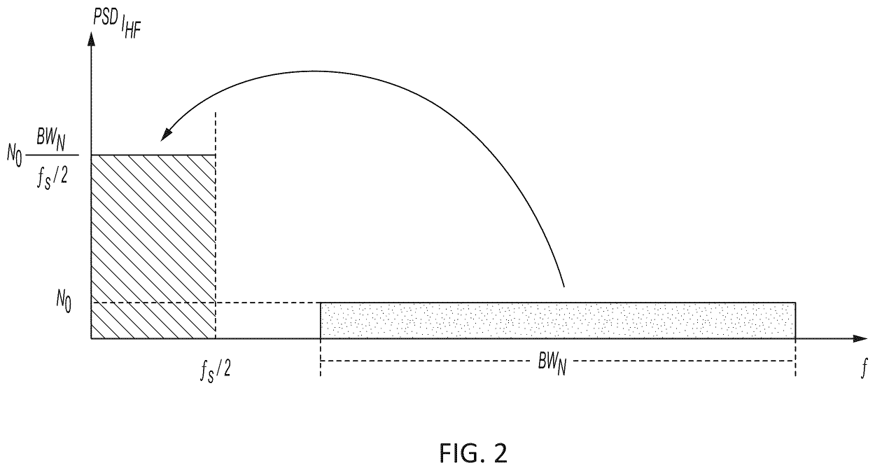

FIG. 2 illustrates an example undersampling process that depicts spectral overlapping induced by undersampling assuming a flat bandpass noise figure, according to embodiments of the present disclosure. The Nyquist-Shannon sampling theorem establishes that a signal should be sampled with a uniform rate at least twice as high as its bandwidth so that it can be reconstructed from interpolation of the resulting digital sequence. Not meeting this criterion distorts the original signal by folding back its spectral content into the Nyquist band (i.e. fₛ/2) in an aliasing process. However, despite this distortion the total power content of the original analog signal is preserved on the sampled sequence which exhibits an increase in power density proportional to the reduction of the effective bandwidth. Undersampling, i.e., using sampling rates smaller than twice the targeted bandwidth can be used to estimate the total in-band power when no signal reconstruction is used or pursued. FIG. 2 depicts a schematic representation of this process where the relationship between the original (N₀) and digitized noise densities and analog (BW_{N}) and Nyquist (fₛ/2) bandwidths are depicted. In FIG. 2, the digitized signal exhibits an increase in noise density proportional to the undersampling rate BW_{N}/(fₛ/2), thereby preserving the integral power (N₀·BW_{N}) of the original signal.

The undersampling scheme features described herein exploits the above described property to estimate relevant arc-induced noise bands in the megahertz (MHz) range over MHz-level bandwidths from signals acquired using sampling rates that are in the tens of kilohertz (kHz) thereby largely reducing the cost of the digitization stage. Time variations of the total power whose frequency content lies within the Nyquist band are also preserved in the aliased signal. This enables the disclosed process to recover the time-correlations of arc-induced noise with line frequencies in the 50-60 hertz (Hz) range.

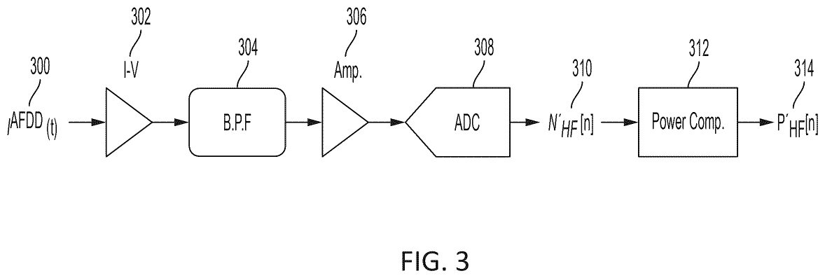

FIG. 3 illustrates an example architecture for acquiring bandpass noise in an undersampling scheme, according to embodiments of the present disclosure. The architecture of FIG. 3 includes line current signal 300, a conversion element 302 which may be the current sensor of FIG. 1 that is sensitive to the MHz bands where arc-induced noise is salient. After conversion (e.g., transforming the current signal to a voltage signal), the architecture of FIG. 3 includes an analog band-pass filter (B.P. F.) 304 that isolates the relevant noise bandwidth to be acquired (i.e., selects a certain range of frequencies of the voltage signal using a filter). The architecture of FIG. 3 includes an operational amplifier 306 that amplifies the certain range of frequencies of the voltage signal to adapt the resulting signal levels to the analog-to-digital converter (ADC) input range. FIG. 3 includes such an ADC component 308 represented as ADC in FIG. 3. This component 308 digitizes the signal on a strong undersampling scheme producing an aliased digitized signal that is represented in FIG. 3 at 310. In embodiments, the integral power on the original band can be estimated from the aliased digitized signal 310 by squaring the individual samples of the aliased digitized signal and time averaging by computing a moving average over certain number of such squared samples. For example, FIG. 3 includes power computation module 312 for computing the power 314 from the aliased digitized signal 310. In embodiments, the power computation module 312 may be performed or be a part of the feature computation 128 of FIG. 1. It should be noted that while the undersampling scheme allows using sampling rates several times smaller than the noise bandwidth to be acquired, the ADC component 308 should still provide an analog bandwidth that matches at least that of the original signal to prevent excessive attenuation before sampling.

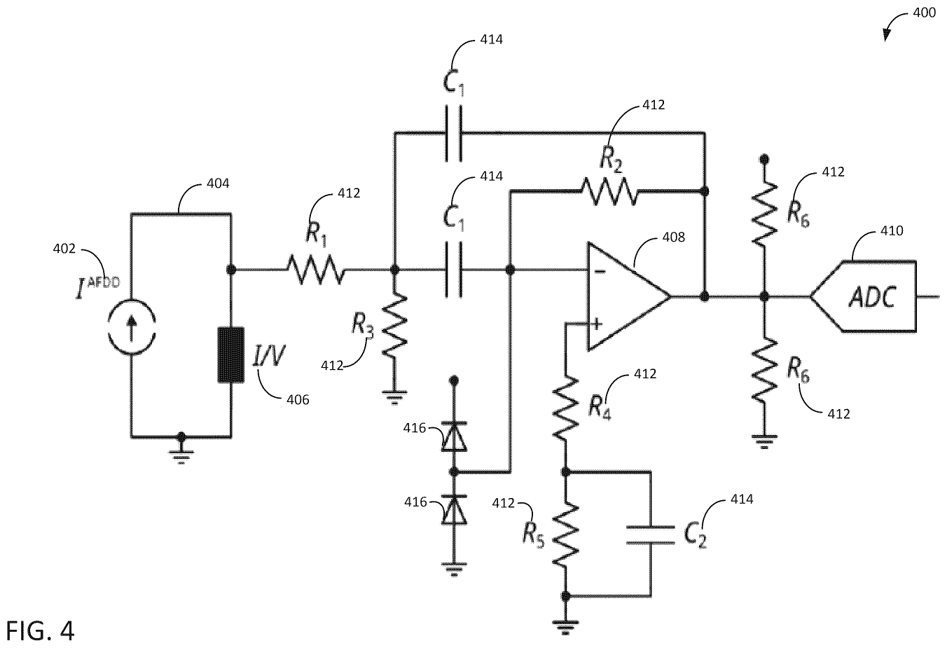

FIG. 4 illustrates an example implementation architecture 400 for acquiring bandpass noise in an undersampling scheme, according to embodiments of the present disclosure. The example implementation architecture 400 is an example of the components 302, 304, 306, and 308 of FIG. 3. The architecture 400 includes the line current 402 for a load 404 as well as current sensor or convert element 406, similar to the conversion element 302 of FIG. 3, for obtaining a current signal and converting it to a voltage signal as described herein. The architecture 400 includes an operational amplifier 408 and an analog-to-digital converter (ADC) 410 for performing a function similar to that described herein for analog-to-digital conversion component 308 of FIG. 3. FIG. 4 also includes one or more resistors 412, capacitors 414, and diodes 416 that along with the operational amplifier 408 implement the analog band-pass filter (B.P.F.) 304 and amplifier 306 of FIG. 3. Although FIG. 4 depicts a certain number of resistors, capacitors, and diodes, implementations of embodiments described herein are not limited to this number and more or less of these components may be used in an example implementation architecture.

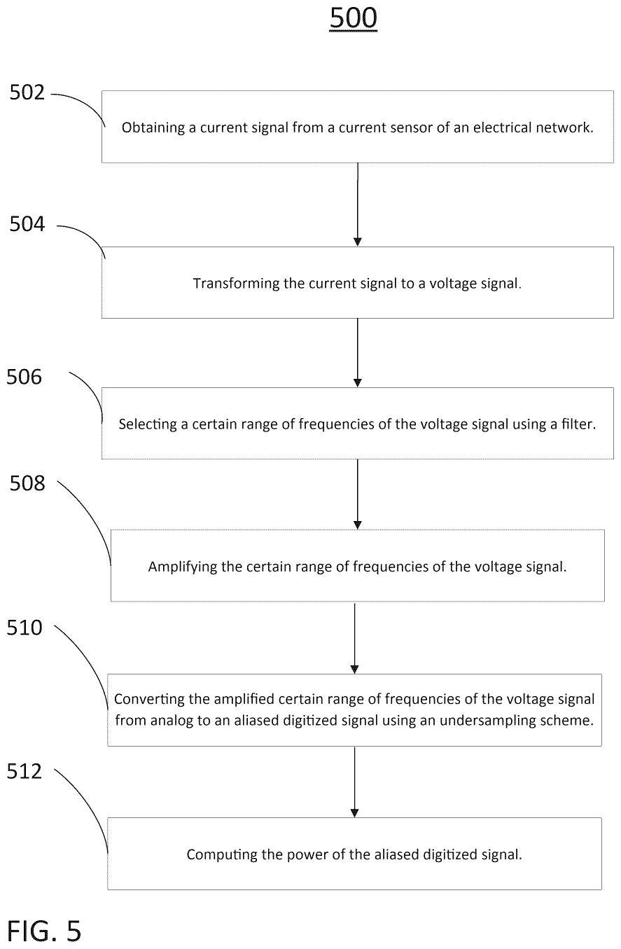

FIG. 5 illustrates an example flow chart for computing a parameter associated with an arc-fault by analyzing a current signal, according to embodiments of the present disclosure. FIG. 5 includes an exemplary process 500 which may be performed by an environment or architecture such as in FIGS. 1, 3, 4, and 6 and by systems and components of FIGS. 1, 3, 4, and 6. However, it will be recognized that any of the following blocks may be performed in any suitable order and that the process 500 may be performed in any environment or architecture and by any suitable computing device and/or controller.

At step 502, the process 500 includes obtaining a current signal from a current sensor of an electrical network. For example, the current sensor may be operated in an electrical network and configured to receive a current signal as depicted in FIG. 1. The process 500 may include, at step 504, transforming the current signal to a voltage signal. In embodiments, the current signal may be transformed to the voltage signal by a current-voltage component as depicted in FIGS. 3 and 4. At step 506, the process 500 may include selecting a certain range of frequencies of the voltage signal using a filter. In embodiments, the certain range of frequencies of the voltage signal may range from 1 MHz to 3 MHz In embodiments, the certain range of frequencies may be determined based on reference data associated with arc-faults detected in a controlled environment. The certain range of frequencies of the voltage signal may include frequencies which are typically associated with arc-faults.

The process 500 includes, at step 508, amplifying the certain range of frequencies of the voltage signal. At step 510, the process 500 includes converting the amplified certain range of frequencies of the voltage signal from analog to an aliased digitized signal using an undersampling scheme. In an embodiment, the voltage signal may be converted from analog to the aliased digitized signal by an analog-to-digital conversion component as depicted in FIGS. 1, 3, and 4. In accordance with at least one embodiment, the undersampling scheme may include using an undersampling rate of at least 64 kilosamples per second. At step 512, the process 500 includes computing a power of the aliased digitized signal. In embodiments, the power may be computed using squaring and time averaging of the aliased digitized signal. The time averaging may be performed in millisecond time scales.

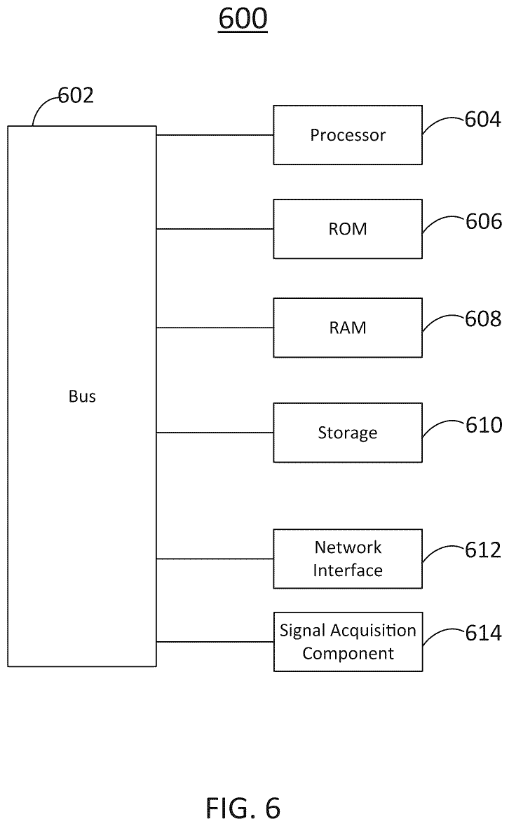

FIG. 6 illustrates a simplified block diagram of one or more devices or systems for computing a parameter associated with an arc-fault by analyzing a current signal according to embodiments of the present disclosure. FIG. 6 is a block diagram of an exemplary system or device 600 within an electrical network associated with a residence or business or some other building such as facility or factory. The system 600 includes a processor 604, such as a central processing unit (CPU), and/or logic, that executes computer executable instructions for performing the functions, processes, and/or methods described herein. In some examples, the computer executable instructions are locally stored and accessed from a non-transitory computer readable medium, such as storage 610, which may be a hard drive or flash drive. Read Only Memory (ROM) 606 includes computer executable instructions for initializing the processor 604, while the random-access memory (RAM) 608 is the main memory for loading and processing instructions executed by the processor 604.

The network interface 612 may connect to a wired network or cellular network and to a local area network or wide area network. The system 600 may also include a bus 602 that connects the processor 604, ROM 606, RAM 608, storage 610, the network interface 612, and signal acquisition component 614. The components within the system 600 may use the bus 602 to communicate with each other. The components within the system 600 are merely exemplary and might not be inclusive of every component for embodiments described herein. For instance, in some examples, the system 600 might not include a network interface 612. In embodiments the system 600 may include one or more components, such as signal acquisition component 614 for obtaining or otherwise receiving analog data such as analog data associated with a current signal of an electrical network that has been transformed to a voltage signal, had certain frequencies selected that were amplified, and converted from analog to an aliased digitized signal. The system or device 600 may include additional components for interacting with a machine or system executing an automated process such as for tripping breakers of the electrical network. The system 600 may communicate with one or more external components or devices for comparing the computed power to a threshold and making a decision to trip the breaker of the electrical network. Other information from the electrical network (e.g. other parameters such as information associated with low frequency bands of a current signal) may be used to determine whether an arc-fault is present in the electrical network and to trip an associated breaker. In such scenarios, the computed power may be provided or transmitted to other computers, devices, components via the network interface 612. In accordance with at least one embodiment, the system 600 may be configured to compare the computed power of the aliased digitized signal to a threshold to determine whether an arc-fault is present in the electrical network as well as instruct, directly, a breaker of the electrical network to trip to prevent the arc-fault to induce a fire hazard. The system 600 may use other information and/or parameters obtained from low-frequency channels of the current signal of the electrical network along with the computed power to determine whether an arc-fault is present in the electrical network.

While the disclosure has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present disclosure covers further embodiments with any combination of features from different embodiments described above and below. Additionally, statements made herein characterizing the disclosure refer to an embodiment of the disclosure and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. A computer-implemented method for computing a parameter associated with an arc-fault in an electrical network by analyzing a current signal comprising:
obtaining the current signal from a current sensor of the electrical network;
transforming the current signal to a voltage signal;
selecting a certain range of frequencies of the voltage signal using a filter;
amplifying the certain range of frequencies of the voltage signal;
converting the amplified certain range of frequencies of the voltage signal from analog to an aliased digitized signal using an undersampling scheme; and
computing a power of the aliased digitized signal.

2. The computer-implemented method according to claim 1, further comprising providing the computed power to an external component of the electrical network.

3. The computer-implemented method according to claim 2, wherein the external component is configured to detect an arc-fault in the electrical network by comparing the computed power to a threshold.

4. The computer-implemented method according to claim 3, wherein the external component is configured to trip a circuit breaker of the electrical network based on detecting the arc-fault.

5. The computer-implemented method according to claim 1, wherein the undersampling scheme uses a sampling rate that is less than a minimum sampling rate defined by a Nyquist-Shannon sampling theorem for the selected certain range of frequencies of the voltage signal.

6. The computer-implemented method according to claim 1, wherein computing the power includes squaring and time averaging the aliased digitized signal.

7. The computer-implemented method according to claim 6, wherein the time averaging is performed in millisecond time scales.

8. The computer-implemented method according to claim 1, wherein the undersampling scheme uses an undersampling rate of at least 64 kilosamples per second and the certain range of frequencies is from 1 megahertz (MHz) to 3 MHz.

9. The computer-implemented method according to claim 1, wherein the filter is implemented by a band pass filter that includes a certain number of capacitors and a certain number of resistors arranged between a current-voltage component, an operational amplifier, and an analog-to-digital conversion component.

10. The computer-implemented method according to claim 9, wherein the current signal is transformed to the voltage signal via the current-voltage component, the certain range of frequencies of the voltage signal are amplified via the amplifier, and the amplified certain range of frequencies of the voltage signal are converted from analog to the aliased digitized signal by the analog-to-digital conversion component, the analog-to-digital conversion component using a certain undersampling rate of the undersampling scheme, the power computed by a feature computation component.

11. The computer-implemented method according to claim 10, wherein the certain range of frequencies is based on reference data associated with arc-faults detected in a controlled environment.

12. A computer system for computing a parameter associated with an arc-fault in an electrical network by analyzing a current signal, the computer system comprising one or more hardware processors which, alone or in combination, are configured to provide for execution of the following steps:
obtaining the current signal from a current sensor of the electrical network;
transforming the current signal to a voltage signal;
selecting a certain range of frequencies of the voltage signal using a filter;
amplifying the certain range of frequencies of the voltage signal;
converting the amplified certain range of frequencies of the voltage signal from analog to an aliased digitized signal using an undersampling scheme; and
computing a power of the aliased digitized signal.

13. The computer system according to claim 12, further comprising further comprising providing the computed power to an external component of the electrical network.

14. The computer system according to claim 13, wherein the external component is configured to detect the arc-fault in the electrical network by comparing the computed power to a threshold.

15. The computer system according to claim 14, wherein the external component is configured to trip a circuit breaker of the electrical network based on detecting the arc-fault.

16. The computer system according to claim 12, wherein the undersampling scheme uses a sampling rate that is less than a minimum sampling rate defined by a Nyquist-Shannon sampling theorem for the selected certain range of frequencies of the voltage signal.

17. The computer system according to claim 12, wherein computing the power includes squaring and time averaging the aliased digitized signal.

18. A tangible, non-transitory computer-readable medium having instructions thereon which, upon being executed by one or more processors, provide for computing a parameter associated with an arc-fault in an electrical network by analyzing a current signal by execution of the following steps:
obtaining the current signal from a current sensor of the electrical network;
transforming the current signal to a voltage signal;
selecting a certain range of frequencies of the voltage signal using a filter;
amplifying the certain range of frequencies of the voltage signal;
converting the amplified certain range of frequencies of the voltage signal from analog to an aliased digitized signal using an undersampling scheme; and
computing a power of the aliased digitized signal.

19. The tangible, non-transitory computer-readable medium according to claim 18, further comprising providing the computed power to an external component of the electrical network.

20. The tangible, non-transitory computer-readable medium according to claim 19, wherein the external component is configured to detect the arc-fault in the electrical network by comparing the computed power to a threshold, and wherein the external component is further configured to trip a circuit breaker of the electrical network based on detecting the arc-fault.
